(19) United States
(12) Patent Application Publication
(10) Pub. No.: US 2025/0349537 A1
(43) Pub. Date: Nov. 13, 2025

(54) SEMICONDUCTOR STRUCTURE AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/897,549

(22) Filed: Sep. 26, 2024

(30) Foreign Application Priority Data
May 11, 2024 (CN) 202410585135.2

(51) Int. Cl. H01L 21/02; C30B 29/40; C30B 29/42; H01L 29/20; H01L 29/778; H01L 33/06; H01L 33/32

(52) U.S. Cl. CPC H01L 21/0243; C30B 29/40; C30B 29/406; C30B 29/42; H01L 21/02499; H01L 21/0254; H10D 30/475; H10D 62/8503; H10H 20/812; H10H 20/825

(57) ABSTRACT

A semiconductor structure includes: a miscut angle substrate, where the miscut angle substrate includes an upper surface and a lower surface opposite to each other, and a plurality of trenches are formed from the upper surface; and a first epitaxial layer, where the first epitaxial layer is located in the plurality of trenches, where each trench of the plurality of trenches includes a bottom wall end, and a first sidewall and a second sidewall located on two sides of the bottom wall end and opposite to each other, and a first included angle formed by the bottom wall end and the first sidewall is an acute angle. The technical solutions of the present disclosure may reduce a dislocation density of the semiconductor structure.

### CROSS-REFERENCE TO RELATED APPLICATIONS

The present application claims priority to Chinese Patent Application No. 202410585135.2, filed on May 11, 2024, which is hereby incorporated by reference in its entirety.

### TECHNICAL FIELD

The present disclosure relates to the field of semiconductor technologies, and in particular, to a semiconductor structure and a manufacturing method for the semiconductor structure.

### BACKGROUND

With a development of science and technology, group III-V compound semiconductors are typically represented by gallium nitride (GAN), gallium arsenide (GaAs) and indium phosphide (InP), which gradually become a current research hotspot, and are suitable for manufacturing high-speed, high-frequency, high-power and light-emitting electronic devices, and thus have a wide application prospect.

Epitaxial growth of a group III-V compound on a substrate still has many problems to be solved, for example, due to existence of a lattice mismatch, a polarity effect/non-polarity effect, a large thermal expansion coefficient difference between materials and the like, dislocation of heteroepitaxy is easily caused, and the dislocation is mainly a line dislocation of crystal direction. Moreover, when a thickness of a group III-V compound semiconductor film layer reaches a critical value, cracking is prone to occur, resulting in degradation and failure of device performance.

### SUMMARY

In view of this, embodiments of the present disclosure provide a semiconductor structure and a manufacturing method therefor to solve a technical problem of a high number of dislocations in a semiconductor film layer in a related art.

According to an aspect of the present disclosure, a semiconductor structure is provided. The semiconductor structure includes: a miscut angle substrate, where the miscut angle substrate includes an upper surface and a lower surface opposite to each other, and a plurality of trenches are formed from the upper surface; and a first epitaxial layer, where the first epitaxial layer is located in the plurality of trenches, where each trench of the plurality of trenches includes a bottom wall end, and a first sidewall and a second sidewall located on two sides of the bottom wall end and opposite to each other, and a first included angle formed by the bottom wall end and the first sidewall is an acute angle.

According to another aspect of the present disclosure, a manufacturing method for a semiconductor structure is provided. The manufacturing method for the semiconductor structure includes: etching a miscut angle substrate from an upper surface of the miscut angle substrate to form a plurality of trenches, where the miscut angle substrate includes the upper surface and a lower surface opposite to each other, each trench of the plurality of trenches includes a bottom wall end, and a first sidewall and a second sidewall located on two sides of the bottom wall end and opposite to each other, and a first included angle formed by the bottom wall end and the first sidewall is an acute angle; and epitaxially manufacturing a first epitaxial layer in the plurality of trenches.

### BRIEF DESCRIPTION OF THE DRAWINGS

FIG. 1 is a schematic structural diagram of a semiconductor structure according to an embodiment of the present disclosure.

FIG. 2 is a schematic structural diagram of a miscut angle substrate in FIG. 1.

FIG. 3 is a schematic structural diagram of a miscut angle substrate according to another embodiment of the present disclosure.

FIG. 4 is a schematic enlarged view of a surface of a miscut angle substrate according to an embodiment of the present disclosure.

FIG. 5 is a schematic structural diagram of a semiconductor structure according to another embodiment of the present disclosure.

FIG. 6 is a schematic structural diagram of a semiconductor structure according to another embodiment of the present disclosure.

FIG. 7 is a schematic structural diagram of a semiconductor structure according to another embodiment of the present disclosure.

FIG. 8 is a schematic diagram of a three-dimensional structure of a miscut angle substrate according to an embodiment of the present disclosure.

FIG. 9 is a schematic diagram of a three-dimensional structure of a miscut angle substrate according to another embodiment of the present disclosure.

FIG. 10 is a schematic flowchart of a manufacturing method for a semiconductor structure according to an embodiment of the present disclosure.

FIG. 11 to FIG. 14 are schematic structural diagrams of intermediate structures in a manufacturing method for a semiconductor structure according to an embodiment of the present disclosure.

### DETAILED DESCRIPTION OF THE EMBODIMENTS

Technical solutions in embodiments of the present disclosure are described clearly and completely below with reference to the accompanying drawings of the embodiments of the present disclosure. Apparently, the described embodiments are only a part, but not all of the embodiments of the present disclosure.

In order to reduce a dislocation density of a semiconductor structure, the present disclosure provides following technical solutions.

FIG. 1 is a schematic structural diagram of a semiconductor structure according to an embodiment of the present disclosure, and FIG. 2 is a schematic structural diagram of a miscut angle substrate in FIG. 1. As shown in FIG. 1 and FIG. 2, the semiconductor structure includes: a miscut angle substrate 10, where the miscut angle substrate 10 includes an upper surface 201 and a lower surface 202 opposite to each other, and a plurality of trenches 20 are formed from the upper surface 201; and a first epitaxial layer 31 located in the plurality of trenches 20. A trench 20 of the plurality of trenches 20 includes a bottom wall end 23, and a first sidewall 21 and a second sidewall 22 located on two sides of the bottom wall end 23 and opposite to each other, and a first included angle β1 formed by the bottom wall end 23 and the first sidewall 21 is an acute angle.

Specifically, as shown in FIG. 1 and FIG. 2, the first included angle β1 formed by the bottom wall end 23 and the first sidewall 21 is an acute angle, in other words, in a projection direction perpendicular to the bottom wall end 23, an orthographic projection of at least part of the first sidewall 21 falls within the bottom wall end 23. Because an extending direction of dislocations is perpendicular to a plane where the bottom wall end 23 is located, when the first epitaxial layer 31 is grown at the bottom wall end 23 of the trench 20, the first sidewall 21 may terminate the extension of a par of the dislocations (for example, a dislocation B), thereby reducing a dislocation density of the semiconductor structure.

In an embodiment, as shown in FIG. 2, the plane where the bottom wall end 23 is located is not parallel to the upper surface 201 of the miscut angle substrate 10. Optionally, the upper surface of the miscut angle substrate 10 is a (111) crystal plane with a miscut angle. When the trench 20 is formed, the bottom wall end 23 is etched to form a (111) crystal plane without a miscut angle, so that the plane where the bottom wall end 23 is located is not parallel to a plane where a surface, close to a second epitaxial layer 32, of the miscut angle substrate 10 is located.

Optionally, as shown in FIG. 2, an extending direction M of the plane where the bottom wall end 23 is located, facing the upper surface 201 and an extending direction N1 of the trench 20 facing the upper surface 201 are located on different sides of a vertical axis Z, and the vertical axis Z is perpendicular to a plane where the miscut angle substrate 10 is located. Specifically, as shown in FIG. 2, in one trench 20, the vertical axis Z extends vertically upward, the extending direction M is located on a left side of the vertical axis Z and extends obliquely upward, the extending direction N1 is located on a right side of the vertical axis Z and extends obliquely upward, and at this time, a second included angle β2 is formed by the extending direction M and the extending direction N1.

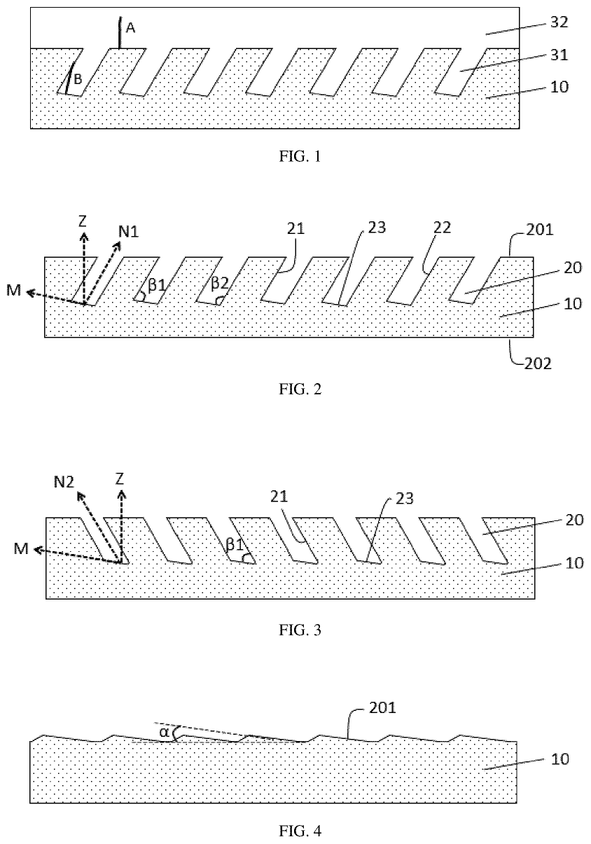

Optionally, FIG. 3 is a schematic structural diagram of a miscut angle substrate according to another embodiment of the present disclosure, as shown in FIG. 3, an extending direction M of a plane where a bottom wall end 23 is located, facing an upper surface 201 and an extending direction N2 of the trench 20 facing an upper surface 201 are located on a same side of a vertical axis Z, and the vertical axis Z is perpendicular to a plane where a miscut angle substrate 10 is located. Specifically, as shown in FIG. 3, in one trench 20, the vertical axis Z extends vertically upward, the extending direction M and the extending direction N2 are both located on a left side of the vertical axis Z and extend obliquely upward, and at this time, a first included angle β1 is formed by the extending direction M and the extending direction N2.

With reference to FIG. 2 and FIG. 3, the extending directions M, facing the upper surface 201, of the planes where the bottom wall ends 23 of the two miscut angle substrates are located respectively remain the same. An etching direction is controlled, in a first type, the etching direction is along the extension direction N1 which is located on a side of the vertical axis Z, the side is different from a side, where the extension direction M is located, of the vertical axis Z, and the miscut angle substrate shown in FIG. 2 is obtained; and in a second type, the etching direction is along the extension direction N2 which is located on a same side of the vertical axis Z as the extension direction M, and the miscut angle substrate shown in FIG. 3 is obtained.

It should be noted that, the upper surface of the miscut angle substrate 10 may be a (111) crystal plane with a miscut angle, this upper surface is taken as an example, and as shown in FIG. 2, a (111) crystal direction extends in a direction perpendicular to the plane where the bottom wall end 23 is located. An in-depth direction of the trench 20 inside the miscut angle substrate 10 is in an opposite direction of the extending direction N1, and the (111) crystal direction is not collinear with the in-depth direction of the trench 20. Similarly, as shown in FIG. 3, a (111) crystal direction is not collinear with an in-depth direction of the trench 20.

It should be noted that the first included angle β1 formed by the extending direction M and the extending direction N2 is smaller than the second included angle β2 formed by the extending direction M and the extending direction N1, and the miscut angle substrate shown in FIG. 3 is more beneficial to reducing the dislocation density of the semiconductor structure.

Optionally, FIG. 4 is a schematic enlarged view of a surface of a miscut angle substrate according to an embodiment of the present disclosure, as shown in FIG. 4, an upper surface 201 of a miscut angle substrate 10 has a plurality of steps, the plurality of steps may be micro-steps, and an included angle between a step surface of each the micro-steps and a horizontal plane is a miscut angle. During an epitaxial process of a second epitaxial layer 32, the micro-steps may be merged, and a dislocation A (shown in FIG. 1) may be deflected, so that the dislocation A cannot extend to a surface of a first epitaxial layer 31, thereby further reducing a dislocation density.

In an embodiment, as shown in FIG. 1, the semiconductor structure further includes a second epitaxial layer 32, and the second epitaxial layer 32 is located on an upper surface 201 of the miscut angle substrate 10 and is healed with the first epitaxial layer 31. Specifically, the second epitaxial layer 32 may be epitaxial from the upper surface 201 of the miscut angle substrate 10 and the first epitaxial layer 31.

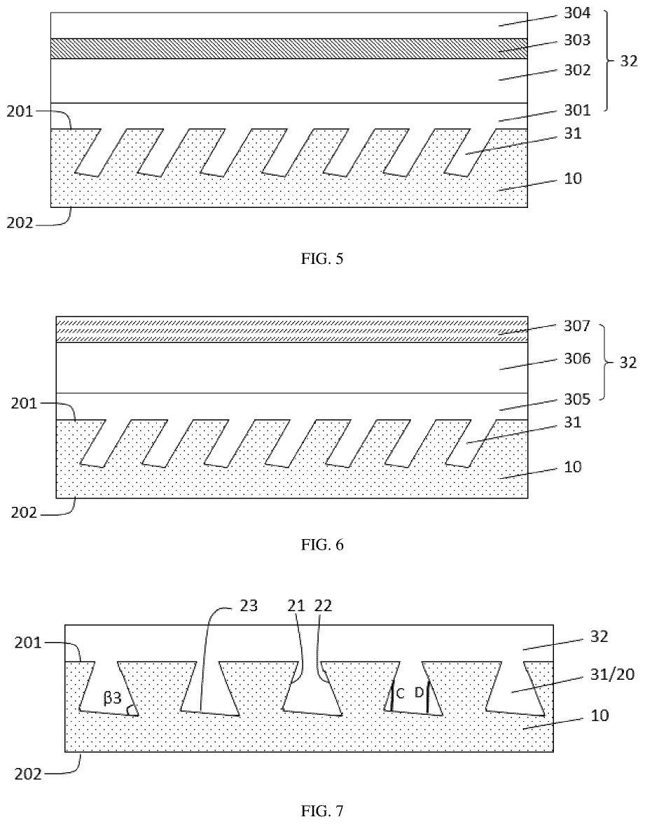

In an embodiment, FIG. 5 is a schematic structural diagram of a semiconductor structure according to another embodiment of the present disclosure, and as shown in FIG. 5, in a direction pointing from a lower surface 202 to an upper surface 201 of a miscut angle substrate 10, a second epitaxial layer 32 includes: an N-type semiconductor layer 302, an active layer 303 and a P-type semiconductor layer 304 that are stacked in sequence. The N-type semiconductor layer 302, the active layer 303 and the P-type semiconductor layer 304 manufactured on the miscut angle substrate 10 have a low dislocation density, which may improve a crystal quality of the semiconductor structure, so as to improve a luminous efficiency of a finally manufactured light-emitting device.

Optionally, taking a second epitaxial layer 32 as an example, the second epitaxial layer 32 is a GaN-based material, the N-type semiconductor layer 302 is an N-type GaN, the active layer 303 is a multi-quantum well layer composed of GaN and GaN-based ternary or quaternary compounds, and the P-type semiconductor layer 304 is a P-type GaN. Optionally, as shown in FIG. 5, the semiconductor structure further includes a buffer layer 301 located between the miscut angle substrate 10 and the N-type semiconductor layer 302, and the buffer layer 301 is configured to heal the epitaxial layer into a flat surface, thereby facilitating subsequent manufacture of a flat semiconductor film layer. Optionally, the first epitaxial layer 31 includes a nucleation layer and a buffer layer. Optionally, an electrode structure is not illustrated in FIG. 5, so the semiconductor structure may be an intermediate structure for manufacturing a light-emitting device.

In an embodiment, FIG. 6 is a schematic structural diagram of a semiconductor structure according to another embodiment of the present disclosure, and as shown in FIG. 6, in a direction pointing from a lower surface 202 to an upper surface 201 of a miscut angle substrate 10, the second epitaxial layer 32 includes: a channel layer 306 and a barrier layer 307 that are stacked in sequence. The channel layer 306 and the barrier layer 307 manufactured on the miscut angle substrate 10 have a lower dislocation density, which may improve a crystal quality of the semiconductor structure, so as to improve a power characteristic of a finally manufactured power device.

Optionally, taking a second epitaxial layer 32 as an example, the second epitaxial layer 32 is a GaN-based material, the channel layer 306 is GaN, and the barrier layer 307 is AlGaN. Optionally, as shown in FIG. 6, the semiconductor structure further includes a buffer layer 305 located between the miscut angle substrate 10 and the channel layer 306, and the buffer layer 305 is configured to heal the epitaxial layer into a flat surface, thereby facilitating subsequent manufacture of a flat semiconductor film layer. Optionally, the first epitaxial layer 31 includes a nucleation layer and a buffer layer.

Optionally, FIG. 4 is a micro-enlarged structure of the upper surface 201 in FIG. 2 and FIG. 3. It should be noted that the miscut angle substrate of the semiconductor structure in other subsequent embodiments is illustrated by the structure shown in FIG. 2.

In an embodiment, the miscut angle substrate 10 is any one of monocrystalline silicon, monocrystalline germanium, monocrystalline silicon germanium, monocrystalline silicon carbide, and sapphire; and/or, a material of the first epitaxial layer 31 includes any one or a combination of a GaN-based material, a GaAs-based material, and an InP-based material.

Specifically, the monocrystalline silicon, the monocrystalline germanium, the monocrystalline silicon germanium, the monocrystalline silicon carbide and the sapphire can all be used as a growth substrate of a group III-V semiconductor film layer. For example, the monocrystalline silicon is used as a growth substrate of a GaN-based material, and lattice constants and thermal expansion coefficients of silicon and GaN are similar, so that a probability of dislocation occurring during the epitaxial growth of the GaN-based material may be reduced. Similarly, the monocrystalline germanium is used as a growth substrate of a GaAs-based material.

Optionally, as shown in FIG. 2, when the miscut angle substrate is monocrystalline silicon, monocrystalline germanium or monocrystalline silicon germanium, the crystal plane of the miscut angle substrate 10 is a (111) crystal plane, and a miscut angle ranges from 0.1 degrees to 20 degrees. The (111) crystal plane is more beneficial to subsequent epitaxial growth of the second epitaxial layer 32. Specifically, the miscut angle is obtained by mechanical beveling.

Optionally, as shown in FIG. 2, a crystal plane of the bottom wall end 23 is a (111) crystal plane, and the (111) crystal plane is more beneficial to subsequent epitaxial growth of the first epitaxial layer 31. Specifically, the (111) crystal plane of the monocrystalline silicon may be formed by alkaline solution etching.

Optionally, as shown in FIG. 2, when the miscut angle substrate is monocrystalline silicon carbide or sapphire, a crystal plane of the miscut angle substrate 10 is a (0001) crystal plane, a miscut angle ranges from 0.1 degrees to 20 degrees, and the (0001) crystal plane is more beneficial to subsequent epitaxial growth of the second epitaxial layer 32.

Specifically, the miscut angle α is appropriately increased, which may improve a possibility that the dislocations end at a sidewall of a via, thereby further reducing the dislocation density of the semiconductor structure; however, when the miscut angle is greater than 30 degrees, the crystal plane of the surface (the upper surface 201 and the bottom wall end 23) may change, resulting in a decrease in an epitaxial rate.

Alternatively, the miscut angle α ranges from 0.2 degrees to 8 degrees. Specifically, due to physical characteristics of materials of the substrate and the semiconductor, a small-angle miscut angle α may further improve the dislocation density. Optionally, the miscut angle α is 0.2 degrees, 0.8 degrees, 1 degree, 2 degrees, 4 degrees, or 8 degrees, and a person skilled in the art may select a suitable miscut angle value according to actual needs. For example, when the miscut angle substrate is sapphire, the miscut angle is 0.2 degrees; and when the miscut angle substrate is GaN or SiC, the miscut angle is 4 degrees.

In an embodiment, as shown in FIG. 2, the second included angle β2 formed by the bottom wall end 23 and the second sidewall 22 is an obtuse angle. Optionally, the first sidewall 21 is parallel to the second sidewall 22. Specifically, the trench 20 is formed by dry etching to form the first sidewall 21 and the second sidewall 22 which are parallel to each other, and the second included angle β2 formed by the bottom wall end 23 and the second sidewall 22 is an obtuse angle by controlling the etching direction.

Optionally, the first included angle β1 formed by the bottom wall end 23 and the first sidewall 21 and the second included angle β2 formed by the bottom wall end 23 and the second sidewall 22 add up to 180 degrees.

Optionally, an orthographic projection, on the bottom wall end 23, of the first sidewall 21 completely covers the bottom wall end 23, and when the first epitaxial layer 31 is epitaxially grown in the trench 20, most of the dislocations perpendicular to the bottom wall end 23 terminate at the first sidewall 21, which may further reduce the dislocation density.

In an embodiment, FIG. 7 is a schematic structural diagram of another semiconductor structure according to an embodiment of the present disclosure, and as shown in FIG. 7, along a direction pointing from a lower surface 202 to an upper surface 201 of the miscut angle substrate 10, a cross-sectional area, on a plane parallel to the miscut angle substrate 10, of a trench 20 gradually decreases. Specifically, along the direction pointing from the lower surface 202 of the miscut angle substrate 10 to the upper surface 201 of the miscut angle substrate 10, the trench 20 has an adducent sidewall, so that at least part of a dislocation C and a dislocation D of a first epitaxial layer 31 may be terminated, and may not extend into a minimum cross-section of the trench 20 in the first epitaxial layer 31, thereby reducing a dislocation density.

Optionally, as shown in FIG. 7, a third included angle β3 formed by a bottom wall end 23 and a second sidewall 22 is an acute angle. Specifically, in a direction perpendicular to a plane where the miscut angle substrate 10 is located, a cross-sectional shape of the trench 20 is similar to a trapezoid, and at least a part of dislocations is terminated by a first sidewall 21 and the second sidewall 22. For example, the dislocation C is terminated by the first sidewall 21, and the dislocation D is terminated by the second sidewall 22. Therefore, the higher a proportion of the orthographic projection, on the bottom wall end 23, of the first sidewall 21 and the second sidewall 22 covering the bottom wall end 23, the better an effect of improving a dislocation problem. Optionally, a first included angle β1 formed by a bottom wall end 23 and a first sidewall 21 is equal to a third included angle β3 formed by the bottom wall end 23 and a second sidewall 22. Optionally, a first included angle β1 formed by a bottom wall end 23 and a first sidewall 21 is not equal to a third included angle β3 formed by the bottom wall end 23 and a second sidewall 22.

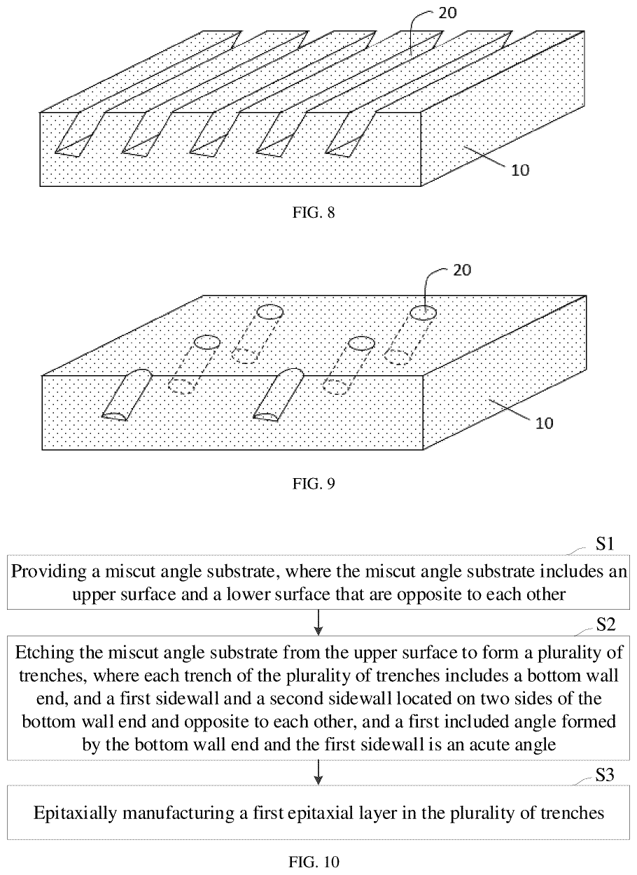

Optionally, FIG. 8 is a schematic diagram of a three-dimensional structure of a miscut angle substrate according to an embodiment of the present disclosure, and as shown in FIG. 8, the trenches 20 in a miscut angle substrate 10 are strip-shaped and arranged at intervals. Optionally, FIG. 9 is a schematic diagram of a three-dimensional structure of a miscut angle substrate according to another embodiment of the present disclosure, and as shown in FIG. 9, the trenches 20 in the miscut angle substrate 10 are inclined cylindrical and arranged at intervals. Optionally, the trenches 20 are inclined hexagonal prisms or other shapes of prisms.

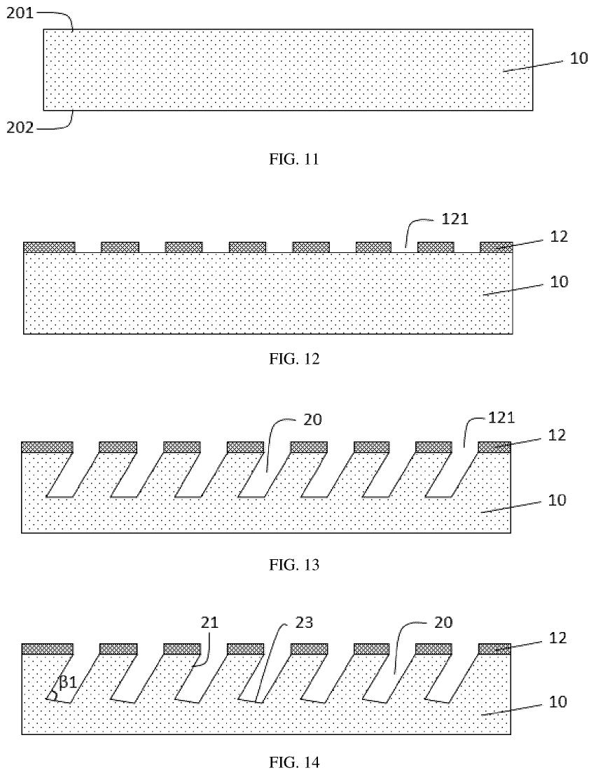

An embodiment of the present disclosure further provides a manufacturing method for a semiconductor structure, FIG. 10 is a schematic flowchart of a manufacturing method for a semiconductor structure according to an embodiment of the present disclosure, and FIG. 11 to FIG. 14 are schematic structural diagrams of intermediate structures in a manufacturing method for a semiconductor structure according to an embodiment of the present disclosure. As shown in FIGS. 11 to 14, the manufacturing method includes following contents.

Step S1, as shown in FIG. 11, providing a miscut angle substrate 10, where the miscut angle substrate 10 includes an upper surface 201 and a lower surface 202 that are opposite to each other.

Specifically, the miscut angle substrate 10 may be commercially available, or may be a substrate that obtains a specific crystal plane, and then a miscut angle α may be obtained by performing miscut. The miscut angle α ranges from 0.1 degrees to 20 degrees. Further, the miscut angle α ranges from 0.2 degrees to 8 degrees.

Step S2, as shown in FIG. 2, etching the miscut angle substrate from the upper surface 201 to form a plurality of trenches 20, where each trench 20 of the plurality of trenches 20 includes a bottom wall end 23, and a first sidewall 21 and a second sidewall 22 located on two sides of the bottom wall end 23 and opposite to each other, and a first included angle β1 formed by the bottom wall end 23 and the first sidewall 21 is an acute angle, so that a projection, on a plane where the bottom wall end 23 is located, of at least part of the first sidewall 21 falls within the bottom wall end 23.

Optionally, in step S2, the etching the miscut angle substrate from the upper surface 201 to form a plurality of trenches 20 includes: as shown in FIG. 12, forming a mask layer 12 patterned on a side of the miscut angle substrate 10, where the mask layer 12 includes a plurality of openings 121 exposing the miscut angle substrate 10; and as shown in FIG. 13, etching the miscut angle substrate 10 at the plurality of openings 121 to form the plurality of trenches 20, where the plurality of openings 121 are respectively communicated with the plurality of trenches 20.

Optionally, a material of the mask layer 12 is silicon oxide, and the plurality of openings 121 are formed by photolithography.

Specifically, as shown in FIG. 14, a dry etching angle is controlled to make an included angle at a bottom of each of the plurality of trenches 20 be an acute angle; and then, the included angle at the bottom of each of the plurality of trenches 20 is obtained as a first included angle β1 by performing another process. Optionally, when the miscut angle substrate 10 is monocrystalline silicon, monocrystalline germanium or monocrystalline silicon germanium, after the plurality of trenches 20 shown in FIG. 7 are obtained, the manufacturing method further includes: treating the plurality of trenches 20 with an alkaline solution to obtain an intermediate structure of the semiconductor structure as shown in FIG. 8, so that a crystal plane of the bottom wall end 23 is a (111) crystal plane, and the (111) crystal plane is more beneficial to subsequent epitaxial growth of the epitaxial layer.

Optionally, step S2 further includes: as shown in FIG. 2, removing the mask layer 12 to obtain the miscut angle substrate 10 with the plurality of trenches 20.

Step S3, as shown in FIG. 1, epitaxially manufacturing a first epitaxial layer 31 in the plurality of trenches 20.

Specifically, the first included angle β1 formed by the bottom wall end 23 and the first sidewall 21 is an acute angle, in other words, in a projection direction perpendicular to the bottom wall end 23, an orthographic projection of at least part of the first sidewall 21 falls within the bottom wall end 23. Because an extending direction of dislocations is perpendicular to the plane where the bottom wall end 23 is located and is same as an epitaxial growth direction of the first epitaxial layer 31, when the first epitaxial layer 31 is grown at the bottom wall end 23 of the trench 20, the first sidewall 21 may terminate the extension of a part of the dislocations (for example, a dislocation A), thereby reducing a dislocation density of the semiconductor structure.

Embodiments of the present disclosure provide a semiconductor structure and a manufacturing method therefor. The semiconductor structure includes: a miscut angle substrate, where the miscut angle substrate includes an upper surface and a lower surface opposite to each other, and a plurality of trenches are formed from the upper surface. A trench of the plurality of trenches includes a bottom wall end, and a first sidewall and a second sidewall located on two sides of the bottom wall end and opposite to each other, and a first included angle formed by the bottom wall end and the first sidewall is an acute angle. During epitaxial growth, a first epitaxial layer is epitaxially grown from the bottom wall end, and the first sidewall may terminate the extension of a part of the dislocations, thereby reducing a dislocation density of the semiconductor structure.

It should be understood that the term “including” and its modification used in this disclosure are open-ended, that is, “including but not limited to”. The term “an embodiment” represents “at least one embodiment”. In this specification, specific features, structures, materials, or characteristics described may be incorporated in an appropriate manner in any one or more embodiments or examples. In addition, without being contradictory, a person skilled in the art may combine and permutate different embodiments or examples described in this specification and features of different embodiments or examples.

What is claimed is:

1. A semiconductor structure, comprising:
a miscut angle substrate, wherein the miscut angle substrate comprises an upper surface and a lower surface opposite to each other, and a plurality of trenches are formed from the upper surface; and
a first epitaxial layer, wherein the first epitaxial layer is located in the plurality of trenches,
wherein each trench of the plurality of trenches comprises a bottom wall end, and a first sidewall and a second sidewall located on two sides of the bottom wall end and opposite to each other, and a first included angle formed by the bottom wall end and the first sidewall is an acute angle.

2. The semiconductor structure according to claim 1, wherein a second included angle formed by the bottom wall end and the second sidewall is an obtuse angle.

3. The semiconductor structure according to claim 2, wherein the first sidewall is parallel to the second sidewall.

4. The semiconductor structure according to claim 1, wherein along a direction pointing from the lower surface of the miscut angle substrate to the upper surface of the miscut angle substrate, a cross-section area, on a plane parallel to the miscut angle substrate, of the trench gradually decreases.

5. The semiconductor structure according to claim 4, wherein a third included angle formed by the bottom wall end and the second sidewall is an acute angle.

6. The semiconductor structure according to claim 1, wherein a plane where the bottom wall end is located is not parallel to the upper surface of the miscut angle substrate.

7. The semiconductor structure according to claim 6, wherein an extending direction of the plane where the bottom wall end is located, facing the upper surface and an extending direction of the trench facing the upper surface are located on different sides of a vertical axis, and the vertical axis is perpendicular to a plane where the miscut angle substrate is located.

8. The semiconductor structure according to claim 6, wherein an extending direction of the plane where the bottom wall end is located, facing the upper surface and an extending direction of the trench facing the upper surface are located on a same side of a vertical axis, and the vertical axis is perpendicular to a plane where the miscut angle substrate is located.

9. The semiconductor structure according to claim 1, wherein the miscut angle substrate is any one of monocrystalline silicon, monocrystalline germanium, monocrystalline silicon germanium, monocrystalline silicon carbide, and sapphire.

10. The semiconductor structure according to claim 1, wherein a material of the first epitaxial layer comprises any one or a combination of a GaN-based material, a GaAs-based material, and an InP-based material.

11. The semiconductor structure according to claim 9, wherein when the miscut angle substrate is monocrystalline silicon, monocrystalline germanium, or monocrystalline silicon germanium, a crystal plane of the miscut angle substrate is a (111) crystal plane, and a miscut angle of the miscut angle substrate ranges from 0.1 degrees to 20 degrees.

12. The semiconductor structure according to claim 11, wherein a crystal plane of the bottom wall end is a (111) crystal plane.

13. The semiconductor structure according to claim 9, wherein when the miscut angle substrate is monocrystalline silicon carbide or sapphire, a crystal plane of the miscut angle substrate is a (0001) crystal plane, and a miscut angle of the miscut angle substrate ranges from 0.1 degrees to 20 degrees.

14. The semiconductor structure according to claim 1, further comprising:
a second epitaxial layer, wherein the second epitaxial layer is located on the upper surface of the miscut angle substrate and is healed with the first epitaxial layer.

15. The semiconductor structure according to claim 14, wherein the second epitaxial layer comprises an N-type semiconductor layer, an active layer, and a P-type semiconductor layer that are stacked in sequence in a direction pointing from the lower surface to the upper surface of the miscut angle substrate.

16. The semiconductor structure according to claim 14, wherein the second epitaxial layer comprises a channel layer and a barrier layer that are stacked in sequence in a direction pointing from the lower surface to the upper surface of the miscut angle substrate.

17. The semiconductor structure according to claim 1, wherein the upper surface has a plurality of steps, and an included angle between a step surface of each step of the plurality of steps and a horizontal plane is a miscut angle.

18. A manufacturing method for a semiconductor structure, comprising:
etching a miscut angle substrate from an upper surface of the miscut angle substrate to form a plurality of trenches, wherein the miscut angle substrate comprises the upper surface and a lower surface opposite to each other, each trench of the plurality of trenches comprises a bottom wall end, and a first sidewall and a second sidewall located on two sides of the bottom wall end and opposite to each other, and a first included angle formed by the bottom wall end and the first sidewall is an acute angle; and
epitaxially manufacturing a first epitaxial layer in the plurality of trenches.

19. The manufacturing method according to claim 18, wherein the etching a miscut angle substrate from an upper surface of the miscut angle substrate to form a plurality of trenches comprises:
forming a mask layer patterned on a side of the miscut angle substrate, wherein the mask layer comprises a plurality of openings exposing the miscut angle substrate; and
etching the miscut angle substrate at the plurality of openings to form the plurality of trenches, wherein the plurality of openings are respectively communicated with the plurality of trenches.

20. The manufacturing method according to claim 19, wherein when the miscut angle substrate is monocrystalline silicon, monocrystalline germanium or monocrystalline silicon germanium, after the etching the miscut angle substrate at the plurality of openings to form the plurality of trenches, the manufacturing method further comprises:
treating the trench with an alkaline solution to make a crystal plane of the bottom wall end be a (111) crystal plane.
